(19) United States
(12) Patent Application Publication
(10) Pub. No.: US 2012/0019991 A1
(43) Pub. Date: Jan. 26, 2012

(54) PORTABLE ELECTRONIC DEVICE WITH PROJECTION

(75) Inventor: MING-CHUN HSIUNG, Shindian (TW)

(73) Assignee: FIH (HONG KONG) LIMITED, Kowloon (HK)

(21) Appl. No.: 12/968,401

(22) Filed: Dec. 15, 2010

(30) Foreign Application Priority Data
Jul. 21, 2010 (CN) 201020266173.5

(51) Int. Cl. H05K 5/00

(52) U.S. Cl. 361/679.01

(57) ABSTRACT

A portable electronic device includes a base and a cover. The base includes a supporting surface. The cover includes a bottom surface, and the bottom surface opposes the supporting surface when the cover is attached to the base. At least one projection is formed on the bottom surface. The at least one projection resists the base to define a space between the bottom surface and the supporting surface when the cover moves relative to the base.

### BACKGROUND

1. Technical Field

The disclosure relates to portable electronic devices, especially to a portable electronic device with a projection to decrease the friction between a base and a cover.

2. Description of Related Art

Portable electronic devices, such as mobile phones, and notebooks are widely used in our daily life. Conventional portable electronic devices often include a base with a keypad and a cover. The cover is rotatably attached to the base so that the keypad is covered by the cover when the portable electronic device in a closed state. However, when the cover rotates relative to the base, the surface friction between the base and the cover easily allow the base and the cover to become worn.

Therefore, there is room for improvement within the art.

### BRIEF DESCRIPTION OF THE DRAWINGS

Many aspects of the exemplary embodiment of a portable electronic device with a projection can be better understood with reference to the following drawings. The components in the drawings are not necessarily drawn to scale, the emphasis instead being placed upon clearly illustrating the principles of the portable electronic device. Moreover, in the drawings, like reference numerals designate corresponding parts throughout the several views, in which:

FIG. 1 is an assembled, isometric view of a portable electronic device of a first exemplary embodiment.

FIG. 2 is similar to FIG. 1, but viewing the portable electronic device from another aspect.

FIG. 3 is similar to FIG. 1, but showing the portable electronic device in another state.

FIG. 4 is a cross-sectional view of the portable electronic device taken along line IV-IV of FIG. 3.

FIG. 5 is an assembled, isometric view of a portable electronic device of a second exemplary embodiment.

### DETAILED DESCRIPTION

The disclosure is illustrated by way of example and not by way of limitation in the accompanying drawings. It should be noted that references to “an” or “one” embodiment in this disclosure are not necessarily to the same embodiment, and such references can include the meaning of “at least one” embodiment where the context permits.

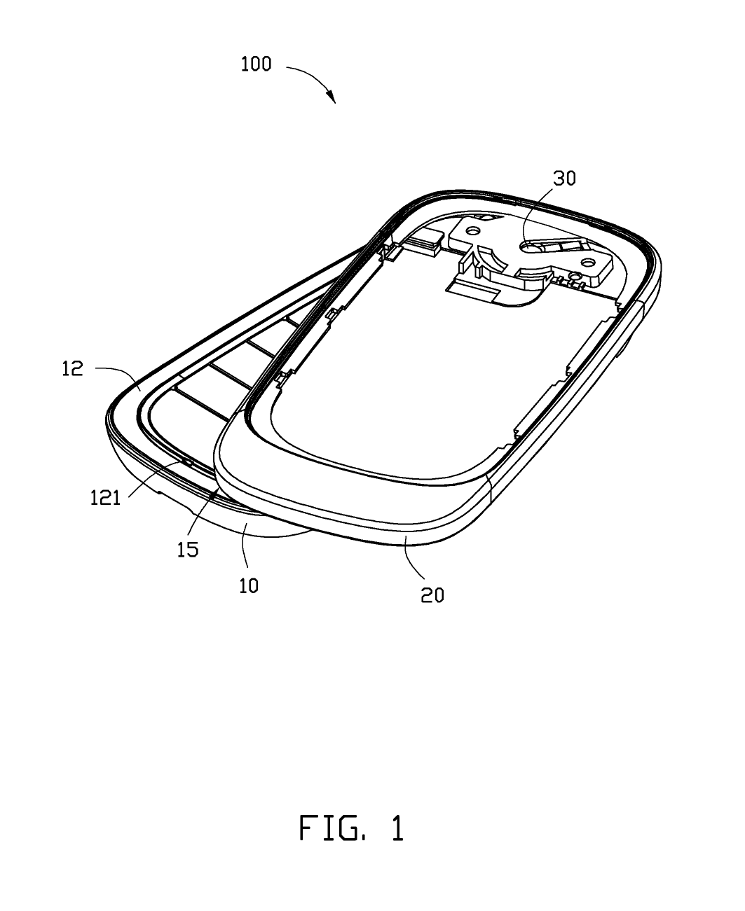

FIG. 1 illustrates a portable electronic device 100 of a first exemplary embodiment. The portable electronic device 100 includes a base 10, a cover 20, and a rotating mechanism 30. The cover 20 is rotatably attached to the base 10 with the rotating mechanism 30. The base 10 includes a supporting surface 12, and the cover 20 includes a bottom surface 22.

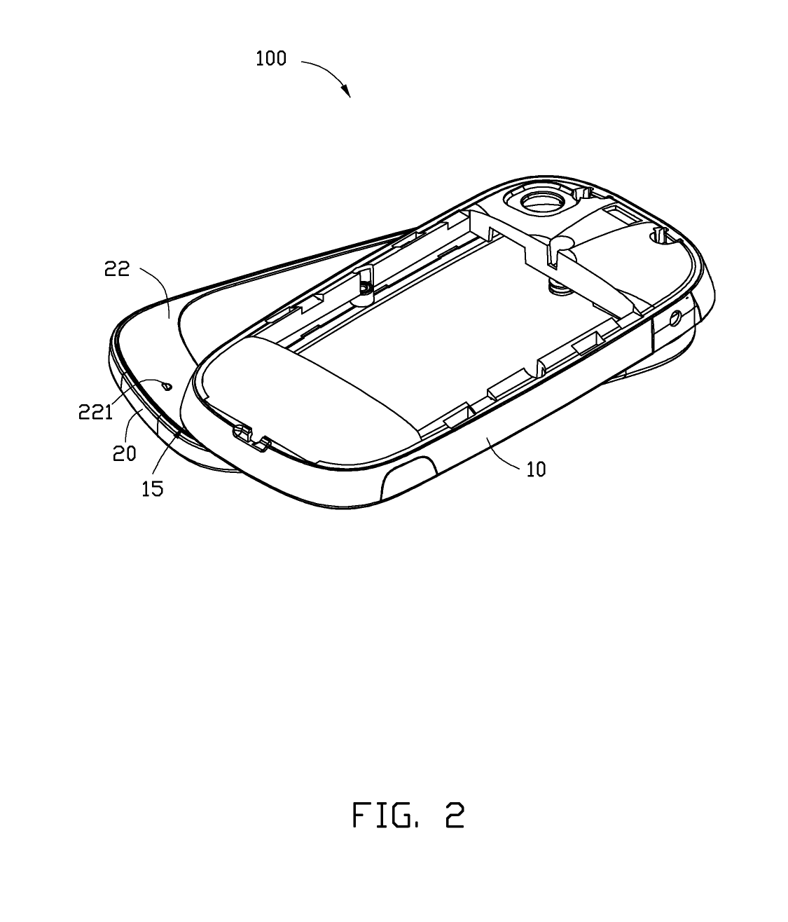

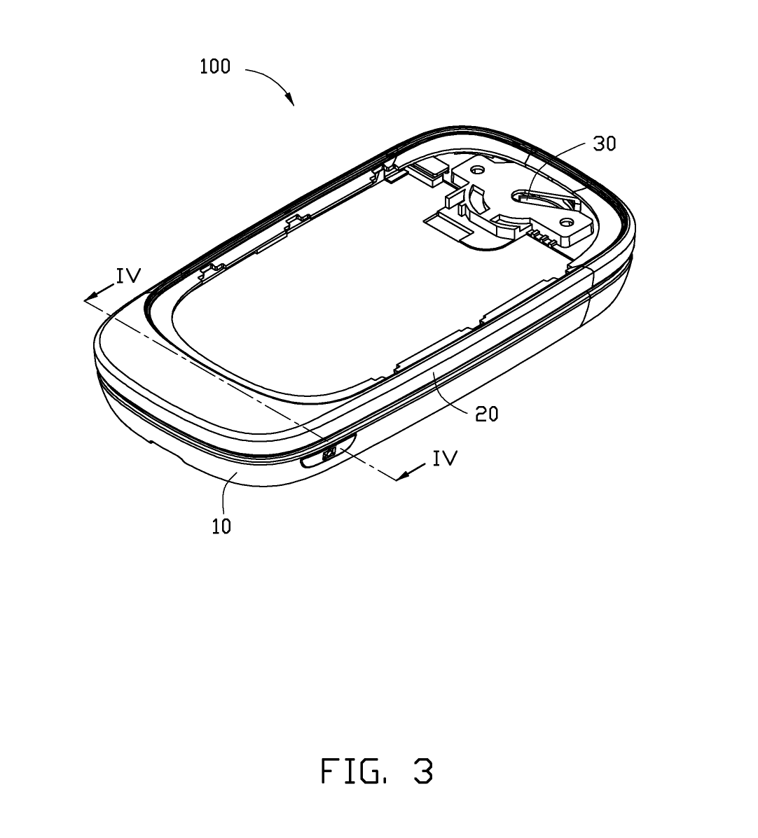

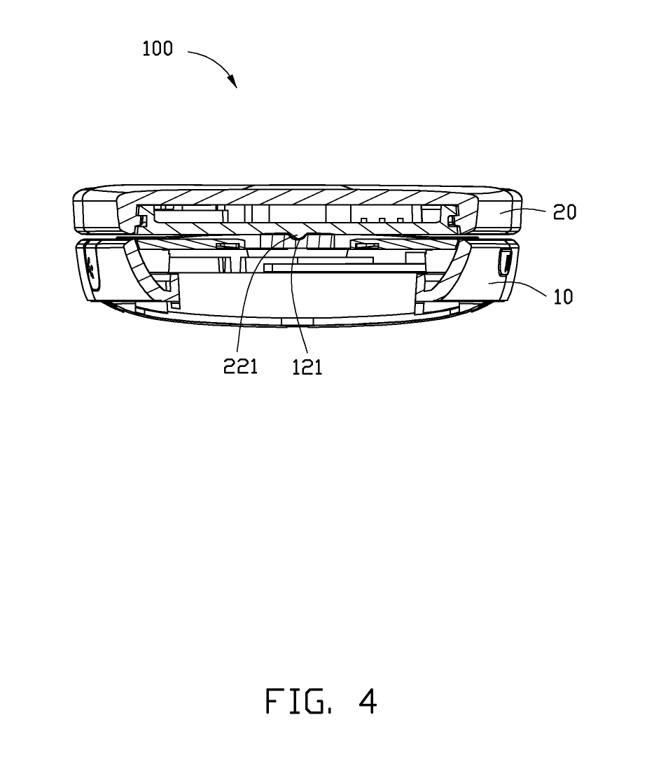

A receiving groove 121 is defined in the supporting surface 12. In the first exemplary embodiment, the receiving groove 121 is defined in the end distal from the rotating mechanism 30. A projection 221 is formed on the bottom surface 22 of the base 20, as shown in FIG. 2. The projection 221 corresponds to the receiving groove 121, when the portable electronic device 100 is in a closed state (see FIG. 3), the projection 221 is received in the receiving groove 121 (see FIG. 4). The projection 221 may be made of one or more self-lubricating materials selected from a group consisting of nylatron, ertalon, and TEFLON (polytetrafluoroethylene).

Referring to FIGS. 1 and 2, when the cover 20 is rotated relative to the base 10, the projection 221 is pushed to move out of the receiving groove 121. When the projection 221 moves out of the receiving groove 121, the projection 221 resists the supporting surface 12 and pushes the cover 20 to define a space 15 between the supporting surface 12 and the bottom surface 22. When the cover 20 rotates relative to the base 10, there is no direct contact between the supporting surface 12 and the bottom surface 22 so the base 10 and the cover 20 will not easily become worn by the friction therebetween. In the exemplary embodiment, the projection 221 is made of self-lubricating material, the friction between the supporting surface 12 and the projection 221 is little, so the projection 221 is easy to move on the base 10.

The rotating mechanism 30 is for rotatably connecting the cover 20 to the base 10. The rotating mechanism 30 can be a hinge, or a pin.

Referring to FIGS. 3 and 4, when the portable electronic device 100 is in a closed state, the projection 221 is received in the receiving groove 121 to assure the cover 20 is oriented at predetermined position of the base 10.

It is to be understood that the projection 221 can be detachably secured to the cover 20 for easy replacement when worn.

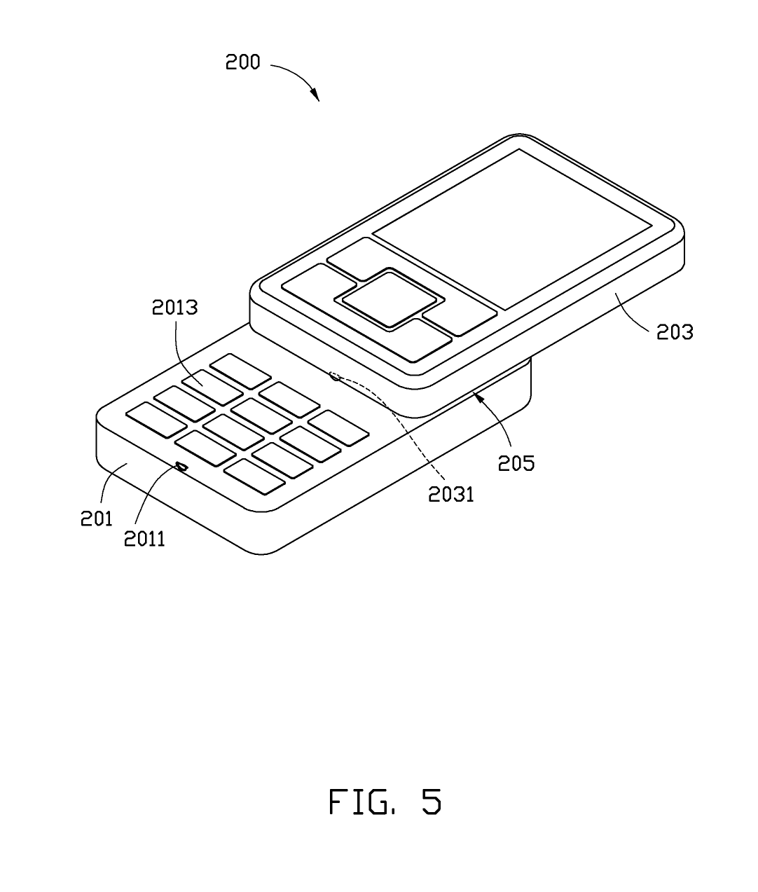

Referring to FIG. 5, in the second embodiment, a portable electronic device 200 is provided. The portable electronic device 200 includes a base 201 and a cover 203, and the cover 203 is slidably attached to the base 201. A receiving groove 2011 is defined in the base 201. A keypad 2013 is formed on the base 201. A projection 2031 of self-lubricating material protrudes from the cover 203. Similarly, the projection 2031 can be detachably secured to the cover 203 for easy replacement when worn.

When the cover 203 is pushed to slide relative to the base 201 to expose the keypad 2013, a space 202 is formed between the cover 203 and the base 201. When the portable electronic device 200 is in a closed state, the keypad 2013 is covered by the cover 203 and the projection 2031 is received in the receiving groove 2011. When the cover 203 slides relative to the base 201, the projection 2031 is pushed to move out of the receiving groove 2011. The projection 2031 pushes the cover 203 upward to form a space 205 between the base 201 and the cover 203 so the base 201 and the cover 203 are apart from each other and the base 201 and the cover 203 will not easily become worn by friction therebetween.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A portable electronic device comprising:
a base including a supporting surface; and
a cover including a bottom surface, the bottom surface facing the supporting surface when the cover attached to the base, at least one projection formed on the bottom surface, the at least one projection resisting the supporting surface of the base to define a space between the bottom surface and the supporting surface when the cover is in an open position relative to the base.

2. The portable electronic device as claimed of claim 1, wherein the projection is detachably secured to the cover.

3. The portable electronic device as claimed of claim 2, wherein the projection is made of self-lubricating material.

4. The portable electronic device as claimed of claim 3, wherein the self-lubricating material is selected from at least one of nylatron, ertalon, and polytetrafluoroethylene.

5. The portable electronic device as claimed of claim 1, wherein a receiving groove is defined in the supporting surface in which the projection is received.

6. The portable electronic device as claimed of claim 1, wherein further including a rotating mechanism, the base rotatably attached to the base by the rotating mechanism.

7. The portable electronic device as claimed of claim 6, wherein the rotating mechanism is a pin or a hinge.

8. The portable electronic device as claimed of claim 1, wherein the cover is slidably attached to the base.

9. A portable electronic device comprising:
a base including a supporting surface; and
a cover including a bottom surface, the bottom surface facing the supporting surface when the cover attached to the base, at least one projection formed on the bottom surface, the projection for separating the supporting from the bottom surface.

10. The portable electronic device as claimed of claim 9, wherein the projection is detachably secured to the cover.

11. The portable electronic device as claimed of claim 10, wherein the projection is made of self-lubricating material.

12. The portable electronic device as claimed of claim 11, wherein the self-lubricating material is selected from at least one of nylatron, ertalon, and polytetrafluoroethylene.

13. The portable electronic device as claimed of claim 9, wherein a receiving groove is defined in the supporting surface in which the projection is received.

14. The portable electronic device as claimed of claim 9, wherein further including a rotating mechanism, the base rotatably attached to the base by the rotating mechanism.

15. The portable electronic device as claimed of claim 14, wherein the rotating mechanism is a pin or a hinge.

16. The portable electronic device as claimed of claim 9, wherein the cover is slidably attached to the base.

17. A portable electronic device comprising:
a base including a supporting surface; and
a cover including a bottom surface, the bottom surface facing the supporting surface when the cover attached to the base, at least one projection formed on the bottom surface, the at least one projection preventing the bottom surface of the cover from directly contacting the supporting surface of the base when the cover moves relative to the base.

18. The portable electronic device as claimed of claim 17, wherein the projection is detachably secured to the cover.

19. The portable electronic device as claimed of claim 17, wherein the projection is selected from at least one of nylatron, ertalon, or polytetrafluoroethylene.

20. The portable electronic device as claimed of claim 17, wherein a receiving groove is defined in the supporting surface in which the projection is received.
